(19) United States
(12) Patent Application Publication
(10) Pub. No.: US 2015/0264808 A1
(43) Pub. Date: Sep. 17, 2015

(54) Solder Attachment of Electrical Components

(71) Applicant: Eric Colin Bretschneider, Bowling Green, KY (US)

(72) Inventor: Eric Colin Bretschneider, Bowling Green, KY (US)

(21) Appl. No.: 14/210,440

(22) Filed: Mar. 14, 2014

(51) Int. Cl. H05K 1/11; H05K 1/02; H05K 3/30; H05K 3/34

(52) U.S. Cl. CPC H05K 1/111; H05K 3/341; H05K 3/3494; H05K 3/3447; H05K 1/115; H05K 1/0298; H05K 3/303

(57) ABSTRACT

A new method of soldering electronic components to printed circuit boards includes a layer of electrical traces with solder pad locations on the top layer. The printed circuit board also includes a series of electrical traces and high electrical resistivity components disposed adjacent to the solder pads.

The process for attaching surface mount components includes at least the following steps: applying solder material to the solder pad locations, placing electronic components on the solder material applied to the solder pads, applying an electrical current to the electrical traces connected to the high electrical resistivity components disposed in proximity to the solder pads. This results in highly localized heat generation via Joule heating in the high resistivity electrical components. The electrical current is maintained long enough to heat the solder material to above its reflow temperature. After the solder material reaches its reflow temperature, the electrical current is discontinued and the solder is allowed to cool and the solder bond formation process is then complete.

### RELATED APPLICATION

This application claims the benefit of priority from U.S. Application No. 61/786,636 filed on Mar. 15, 2013, the contents of which are hereby incorporated by reference as if fully set forth herein.

### BACKGROUND OF THE INVENTION

Surface mount electrical components are typically attached to printed circuit boards using a complex multi step process that requires equipment that occupies a great deal of production floor space and also has a high utility cost to operate. This process involves placing solder paste on electrical pads on a printed circuit board. This is typically done using a screen printing or other processes that are well known in the art. After placing solder paste, surface mount components are then placed on the solder paste and transferring the printed circuit board and components to a reflow oven.

Inside the reflow oven, the entire printed circuit board, solder paste and surface mount components are progressively heated to a temperature above the melting temperature of a solder paste is also known as its reflow temperature. At the end of the process the entire assembly is allowed to cool resulting in solidification of the molten solder material and thus the solder process is completed. The entire reflow process commonly takes between 3-5 minutes to complete. The long process time is necessitated by the low thermal conductivity of fiberglass based printed circuit boards and the need to uniformly heat the solder paste.

In some cases metal core printed circuit boards are used. The metals used in the bulk of this class of printed circuit boards typically have a high thermal conductivity. Even for these types of printed circuit boards still require a long process time for reflow due to the need to uniformly heat the metal core and ensure that the solder paste is heated high enough above its reflow temperature to ensure that strong solder bonds are formed.

Solder reflow ovens commonly include multiple zones and occupy large amount of floor space. These reflow ovens use a conveyor belt apparatus to transfer printed circuit board assemblies through the multiple heated zones. Reflow ovens use these multiple zones to control the temperature profile of the printed circuit boards are exposed to. Printed circuit boards are maintained in regions of constant temperature for extended periods of time to allow heating of the printed circuit board material, electrical components and solder materials to reach a constant temperature. Constant temperature is required to ensure that all of the solder material enters a molten state in order to make reliable electrical contact with the electrical components. Any non-uniformities in temperature may result in solder bonds with poor reliability behavior or even fail to make any electrical contact between the printed circuit board and the electrical components.

The heated zones inside a reflow are heated using convective and/or radiative heating elements. These heating elements may be located above or below the conveyer belt apparatus or both above and below the conveyer belt apparatus. Heating elements are commonly in pairs with one element above the printed circuit board path and one element below the printed circuit path to help ensure uniform heating and minimize process time.

The large numbers of heating elements used in reflow ovens lead to high utility costs for reflow processes. This is due to the high thermal mass of the reflow system and also the fact that the region in each zone must be maintained at high temperature even if no board present in the zone. This also requires a significant start up time in order for the temperature in each zone to stabilize which further increases utility cost. These facts coupled with the large amount of production floor space required for reflow ovens leads to a relatively high process cost.

Another issue with the current method of solder reflow is encountered if a rework step is required. During a rework step, one or more components may need to be removed and replaced on the printed circuit board. This requires careful heating of suspect surface mount components with a soldering iron to melt the solder attaching it, then removing the component, followed by reapplying solder material, placing a new component and then manually applying heat to the solder with a soldering iron to melt it. This process requires a high degree of skill and significant time. It is also prone to failure.

Alternatively rework may be accomplished by placing the circuit board on a hot plate and heating the entire board and all the electrical components to a temperature above the melting point of the solder. Once the solder has been melted, components may be removed and replaced. This process also requires a high degree of skill as all of the solder is returned to a molten state and any physical contact with any component on the board may shift the component off the solder pads. This may induce additional failures and/or defects in the circuit board. Additionally this increases the thermal load imposed on all the components and may lead to decreased lifetime of the entire circuit board assembly or individual components of the circuit board assembly due to prolonged exposure to elevated temperatures. In a similar manner, prolonged exposure to high temperatures may adversely affect the performance of the circuit board assembly.

Yet another issue with current methods of solder bond formation is that it is difficult to attach surface mount components to both sides of a printed circuit board. This can be accomplished by using solder materials with different reflow temperatures on each side of the board, but it greatly complicates any efforts to remove and replace electrical components. It also necessitates careful segregation of solder materials during manufacturing.

Other solder attach methods are also used for through hole components. For these components the solder pads are typically round with a hole in the middle that passes through the entire board. Electrical leads are inserted into the holes and the entire assembly is passed over a molten bath of solder. The solder adheres to the leads of the component as well as the solder pad. This process is known as wave solder and is known in the industry.

It is difficult to solder through hole components to both sides of a printed circuit board using an automated process. Through hole electrical components can not be immersed in molten solder without risk of damage or failure due to molten solder penetrating the component. Through hole electrical components can be mounted on both sides of a printed circuit board if a manual process is used which greatly increases cost and process time.

### BRIEF SUMMARY OF THE INVENTION

The present invention comprises a multi-layer printed circuit board. The layers of the board are preferably made of a material with a high thermal resistivities and a high electrical resistivity. Fiberglass and cellulose materials such as FR4 and CEM are excellent electrical insulators and have very high thermal resistivities. These materials are commonly used for printed circuit boards due to their low cost and ease of production. In particular FR4 and CEM are produced by laminating multiple layers of material together to form a composite board. This lamination process means that FR4 and CEM based boards are well suited for producing boards with multiple layers of electrical conductors. FR4 and CEM are mentioned here as representative materials. It is understood that other materials including ceramics may be used to produce printed circuit boards and that the invention is not limited to these representative examples.

A series of electrical traces and solder pads are disposed on the top layer of the printed circuit board. The electrical traces on the topmost layer are commonly covered with a non-conductive solder mask so that only the solder pads and other electrical contacts are exposed.

The present invention also includes at least one buried layer of electrical traces connected to a series of high electrical resistivity components. The high electrical resistivity components are disposed adjacent to or under the solder pads of the top layer of electrical traces.

Another aspect of the present invention include two or more electrically conductive vias that may extend from the buried series of electrical traces to the uppermost layer of the printed circuit board. These vias may be directly exposed or may be connected to electrically conductive traces that terminate in exposed conductive pads. Alternatively openings may be present in the uppermost layer of the printed circuit board that expose portions of the buried electrical traces.

Solder material application and component placement takes place using methods already known in the art. Solder reflow is accomplished by applying an electrical current to the exposed vias connected to the buried electrical traces connected to the high electrical resistivity components. The electrical current may also be applied to the exposed electrical contacts on the uppermost layer make electrical contact to the buried high electrical resistivity devices through the electrical traces on the uppermost layer of the printed circuit board and the electrically conductive vias that extend from the uppermost layer of the electrical printed circuit board to the buried layer with the high electrically resistive components.

When an electrical current is passed through high electrical resistivity components, heat is generated by a process known as Joule heating. Heat generation is proportional to the electrical resistivity multiplied by the square of the electrical current. This results in highly localized heating. Since the high electrical resistivity components are located proximal to solder pads with solder paste, these pads can be locally heated to above the reflow temperature of the solder. When the current flow ceases, the molten solder cools and solidifies completing the process of solder joint formation.

Once solder pad formation is complete, reapplication of an electrical current to the buried high electrical resistivity components will again cause localized heating at the solder pads of selected components. While the solder is in a molten state, components may be removed and replaced without subjecting the entire assembly to high temperatures again. Careful design of the printed circuit board of this invention may thus allow targeted removal and replacement of components after testing without risk of shifting the location of other components causing additional incidental failures due to components shifting off solder pads while solder is in a molten state resulting in open circuit failures.

In one embodiment of the invention printed circuit boards are prepared with an upper layer of electrical traces and solder pads as outlined previously. Similarly the printed circuit board contains at least one layer of high resistivity electrical components that are located proximal to the solder pads of the uppermost layer. Electrical traces in the buried layer with the high electrical resistivity components connect one or more of these high electrical resistivity electrical components to electrically conductive vias that extend to the uppermost layer of the printed circuit board. These electrical vias may terminate in exposed electrical contacts or may be connected to electrical traces to electrical contact points located at various locations on the uppermost layer of the printed circuit board.

In other embodiments the buried electrical traces connected to high electrical resistivity components may be accessed from the surface of the printed circuit board by openings in the upper layer of the printed circuit board that align with portions of the buried electrical traces. The exact method of making electrical contact to the buried electrically conductive traces and energizing the buried high electrical resistivity components is not critical and many alternative methods will be obvious to those of skill in the art.

Assembly proceeds by applying solder material to the solder pads locations with through holes on the uppermost layer of the printed circuit board. for the through holes for electrical leads. The electrical leads of an electrical component are then inserted into the through holes. An electrical current is then applied to the buried electrical traces connected to the buried high electrical resistivity components. This results in highly localized heating of locations proximal to the buried high electrical resistivity components. Once the solder material is molten and wets the electrical contacts of the electrical component, the current may then be discontinued to allow cooling and solidification of the solder material and completion of solder bond formation.

This method of solder bond formation thus allows simultaneous soldering of both surface mount and through hole components. This process can also easily allow soldering of surface mount components and through hole components on both sides of a printed circuit board. In one embodiment of the current invention electrically conductive traces and solder pads are disposed on both the top and bottom surfaces of the printed circuit board. The printed circuit board will also comprise one or more buried layers with high electrical resistivity components disposed in close proximity to one or more solder pads located on the top or bottom surfaces of the printed circuit board. Electrically conductive traces are also disposed to provide electrical continuity between the high electrical resistivity components and electrically conductive vias that extend from the buried layer to either the top surface or the bottom surface of the printed circuit board.

These electrical vias may terminate on either the top surface or the bottom surface of the printed circuit board and be exposed allowing electrical contact to be made to the buried high electrical resistivity components disposed in close proximity to solder pads. These electrical vias may also be covered by an insulating layer of material commonly known as a solder mask. Electrical traces may extend from these electrical vias under the solder mask to exposed electrical contact pads.

In this embodiment of the invention, solder material is applied to the solder pads on one side of the board. Electrical components are then placed on the solder material if they are surface mount components or are inserted into through holes if they are through hole components. An electrical current is then applied to the buried high electrical resistivity components disposed in close proximity to the solder pads with applied solder material until the solder material is heated above its reflow temperature. The electrical current is then terminated and the molten solder is allowed to cool and solidify.

The printed circuit board is then turned over and the process of applying solder material, placing of electrical components, applying electrical current to the buried high electrical resistivity components disposed in close proximity to the solder pads with applied solder material to heat the solder material above its reflow temperature and termination of the electrical current.

It is understood that solder material is not limited to a single class or group of materials. Solder material is used as a generic description and may refer to any solder alloys or compositions commonly used in the industry for mounting electrical components on a printed circuit board. This may include solder pasts, electroplated solder or solder applied to the solder pads by bulk processes such as wave solder. It may also include manual application of solder material to the solder pads. It also understood that the step of applying solder material may also include application of cleaners or flux agents.

### BRIEF DESCRIPTION OF THE DRAWINGS

Some embodiments of the invention are herein described by way of example only, with reference to the accompanying drawings. With specific reference now to the drawings in detail, it is stress that the particulars shown are by way of example and for purposes of illustrative discussion of embodiments of the invention. In the regard, the description taken with the drawings makes apparent to those skilled in the art how embodiments of the invention may be practiced.

FIG. 1 shows a simplified and representative cross section of a reflow oven that is typically used in a prior art solder reflow process.

FIG. 2 is a representative time and temperature profile that may be used in the reflow oven FIG. 1.

FIG. 3 shows the process flow chart of a prior art solder reflow process.

FIG. 4 shows an illustrative process flow chart of a solder reflow process of the present invention.

FIG. 5 shows an illustrative process flow chart for a printed circuit board rework process of the present invention.

FIG. 6 shows an exploded view of a printed circuit board of the present invention.

FIG. 7 shows an illustrative monitoring process of the present invention.

### DETAILED DESCRIPTION OF DRAWINGS

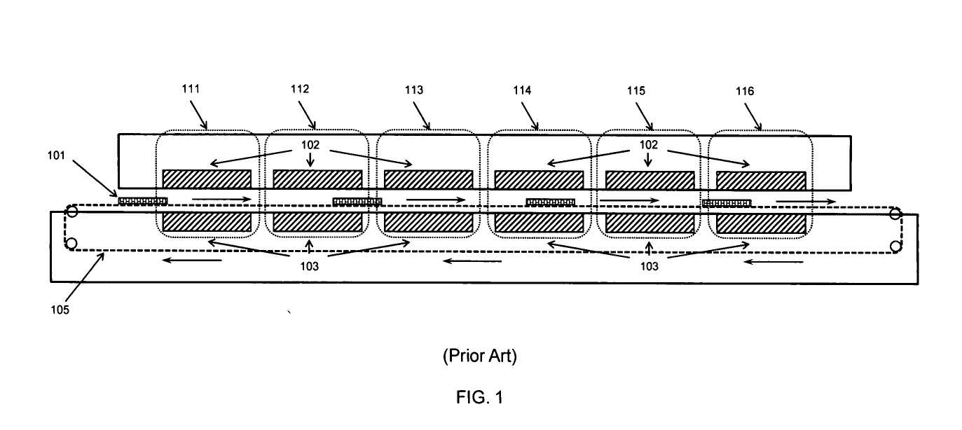

Referring to FIG. 1, a reflow oven of the prior art comprises a series of upper heating elements 102 and lower heating elements 103. These heating elements 102, 103 may operate by radiative heating, convective heating or a combination of radiative and convective heating. These heating elements 102, 103 are disposed above and below a conveyer belt 105 that passed between the heating elements 102, 103. The conveyer belt 105 supports printed circuit board assemblies 101 and moves the printed circuit boards 101 through the reflow oven. The upper heating elements 102 and lower heating elements 103 are disposed in pairs to form heating zones 111, 112, 113, 114, 115, 116. The temperature in each heating zone 111, 112, 113, 114, 115, 116 may be independently adjusted and controlled. The combination of the temperature set point for each heating zone 111, 112, 113, 114, 115, 116 and the conveyer belt 105 speed establish the temperature profile of printed circuit board assemblies 101 during the reflow process.

The printed circuit board assemblies 101 include a printed circuit board with solder material and electrical components. The printed circuit board assemblies 101 may be individual printed circuit boards with solder material and electrical components or may comprise multiple printed circuit boards with solder material and electrical components. The printed circuit board assembly 101 may also include a holder (not shown) or other component to assist in transferring the printed circuit boards with solder material and electrical components through the reflow oven.

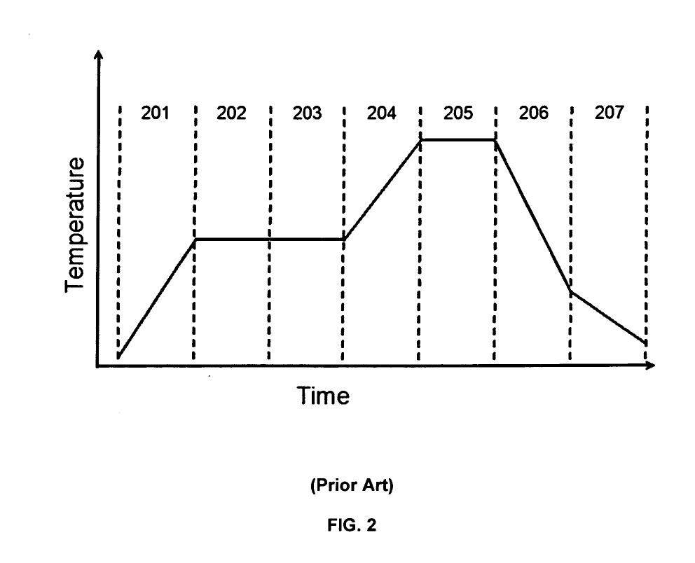

FIG. 2 shows an illustrative temperature versus time profile for the prior art reflow oven of FIG. 1. The temperature profile includes a temperature zone 201, 202, 203, 204, 205, 206 for each corresponding heating zone 111, 112, 113, 114, 115, 116. In this illustrative example temperature zone 1 201 transitions the printed circuit board assembly 101 from room temperature to an elevated temperature. Temperature zones 2 202 and 3 203 are held at an approximately constant temperature known as the pre-heat temperature. The purpose of the pre-heat temperature is to allow the entire printed circuit board assembly 101 to reach an even temperature. This pre-heat step requires an extended period of time and may compromise about 60% to about 75% of the entire time for the reflow process.

After the pre-heat step the printed circuit board assembly 101 enters a ramp zone 204 to raise its temperature to near or above the reflow temperature of the solder material. The printed circuit assembly 101 then enters the reflow temperature zone 205 in which it experiences the maximum temperature of the process. In the reflow temperature zone 205 it is vital that the printed circuit board assembly 101 reaches a temperature above the reflow temperature of the solder material. If the any portion of the printed circuit board assembly 101 does not reach the reflow temperature of the solder material then no solder connection will form and the resulting printed circuit board will either need to be reworked or scrapped.

Because of this the temperature in the reflow zone 205 must be set to a point significantly above the reflow temperature of the solder material. This exposes both the electrical components and the printed circuit board materials to excessively high temperatures that may impact later performance or reliability. The maximum temperature an electrical component may be exposed to is typically available from the supplier or manufacturer. Maximum time at the maximum temperature is also specified by the supplier or manufacturer of the electrical components.

Exceeding either the maximum temperature or the maximum time at high temperature of an electrical component typically results in reduced reliability or lifetime of the electrical components or impair their performance.

This is where the low thermal conductivity of the materials used in composite printed circuit boards such as FR4 and CEM becomes a potentially significant liability. Low thermal conductivity increases the pre-heat temperature requirements and also prolongs the amount of time a printed circuit board spends at any elevated temperature whether it is the pre-heat stage or the reflow stage.

In the final heating zone 206 the temperature is allowed to drop so that the solder material cools and returns to a solid state. The temperature profile shown in FIG. 2 includes an additional temperature zone 207 that does not have a corresponding heat zone. This portion of the temperature profile represents the time when the printed circuit board assembly 101 exits the reflow oven and returns to ambient temperature.

Reflow ovens are not limited in the number of temperature zones they have. Reflow ovens may have a single temperature zone or as many as eight or even more. Having more temperature zones offers increased ability to control the exact temperature profile experienced by the printed circuit board assembly 101, however more temperature zones increases the dimensions of the reflow oven requiring more processing floor space and higher utility requirements. Both of these factors increase the cost of the reflow process.

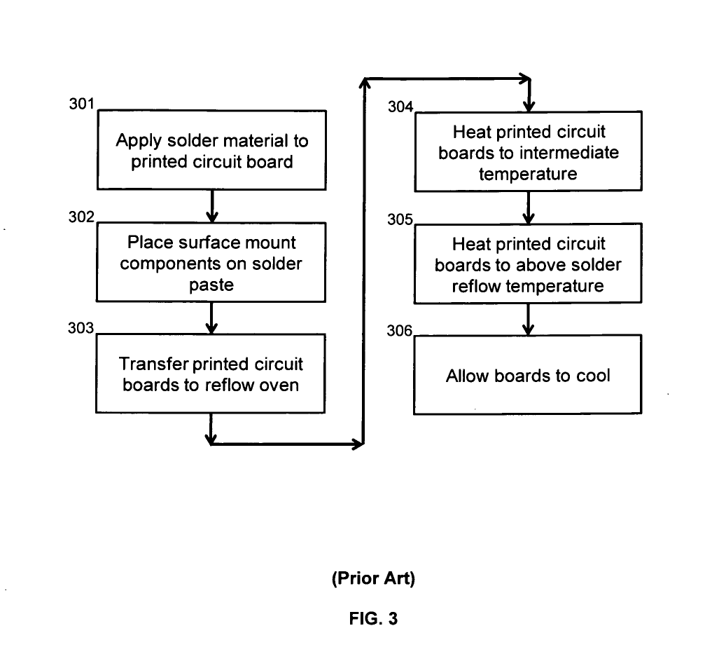

FIG. 3 illustrates the general process flow of a prior art reflow process. In a first step 301 solder material is applied to the printed circuit board. The solder material may be applied by a number of methods known in the art such as electroplating, wave solder application or screen printing of solder paste. The method of solder application is not critical and is not meant to be limited to the illustrative examples listed here.

In the second step 302 electrical components are placed on the solder material. At this point in time there is no significant mechanical bond between the electrical components and the printed circuit board. The printed circuit board must be handled with care as the electrical components may shift if physical contact is made resulting in rework or scrapping of the printed circuit board.

Mechanical pick and place machines are commonly used to places electrical components at this process step. Some physical movement 303 is required to transfer the printed circuit board to the reflow oven. This may require manual movement of the printed circuit board or may be accomplished using a conveyer belt assembly. Regardless there is a significant delay in time between placement of the electrical components and formation of a solder bond.

After the printed circuit board is transferred to the reflow oven is heated to and intermediate temperature 304. The printed circuit board is held at an intermediate temperature for an extended period of time to allow head conduction to take place. During this intermediate temperature step the temperature of the printed circuit board and the electrical components is raised to a high temperature that is still below the reflow temperature of the solder material.

In the next process step 305 the printed circuit board and the electrical components are heated to above the reflow temperature of the solder material. During this process step 305 the solder material enters a molten state and wets both the solder pad on the printed circuit board and the electrical connection point(s) of the electrical component. This wetting process is critical and ensures that electrical connection will be made between the printed circuit board and the electrical component when the solder cools and solidifies. Wetting of the both the solder pad and the electrical connection point(s) of the electrical component also ensures that a strong mechanical bond will be formed between the printed circuit board and the electrical component when the solder cools and solidifies.

In the final step 306 the printed circuit board and electrical components are allowed to cool so that the solder solidifies. This step may take place entirely within the reflow oven or partially in the reflow oven and partially outside the reflow oven. When a reflow oven is used the temperature of the printed circuit board and electrical components is reduced below the reflow temperature of the solder so that it solidifies prior to exiting the reflow oven.

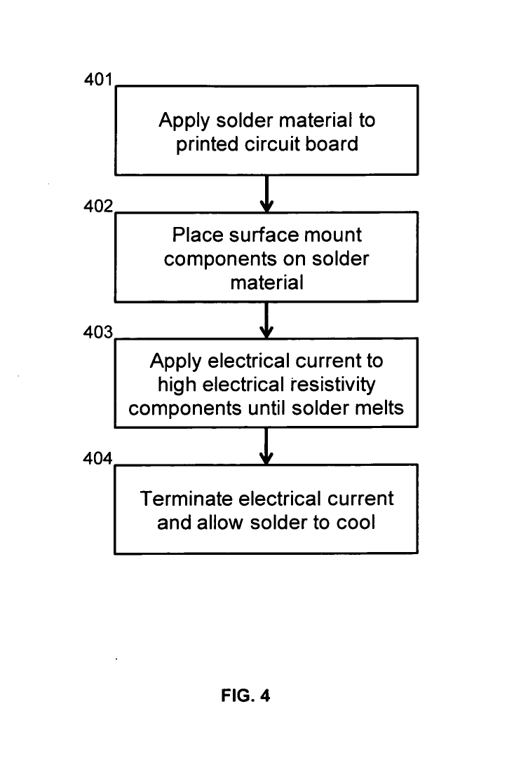

FIG. 4 is a first illustrative process flow diagram of the present invention. In the first step 401 solder material is applied to solder pads 603 on the printed circuit board. The solder material may take a variety of forms such as electroplated solder, waver solder or solder paste. The solder material may also be deposited by a variety of methods including electroplating, wave solder and screen printing. These materials and methods are intended to be illustrative and not restrictive. The invention can be modified to include a number of different solder materials and deposition methods not described here that are known in the art without deviating from the spirit and scope of the invention.

In the second step 402 of the first illustrative process flow surface mount electrical components 620 are placed on the solder materials. Mechanical pick and place machines are commonly used to places electrical components at this process step.

In the third step 403 of the first illustrative process flow an electrical current is applied to buried high electrical resistivity components 613. This results in localized heating. In this manner only the material in close physical proximity to the high electrical resistivity components 613 are heated including the solder pads 603, applied solder material, and the electrical components 620. This process step is maintained until the applied solder material is heated to above its reflow temperature, melts and wets the solder pads 603 and the electrical contact surfaces of the electrical components 620.

In the fourth step 404 of the first illustrative process flow the electrical current applied to the buried high electrical resistivity components 613 is terminated and the solder is allowed to cool and solidify.

This entire process flow can take place in a matter of seconds compared to at best a few minutes for prior art solder reflow processes such as that illustrated in FIGS. 1, 2 and 3. This process flow can occur in a separate stand alone piece of process equipment that occupies much less floor space than a standard reflow oven. In addition since heat is generated in the materials in close physical proximity to the high electrical resistivity components the utility requirement for the process can be reduced by well over 90% or even over 99% compared to a standard reflow process.

It is also possible for this process to be completed in a slightly modified pick and place system. This type of modified pick and place system would produce fully assembled and soldered printed circuit boards in little more floor space than that required for a standard pick and place system.

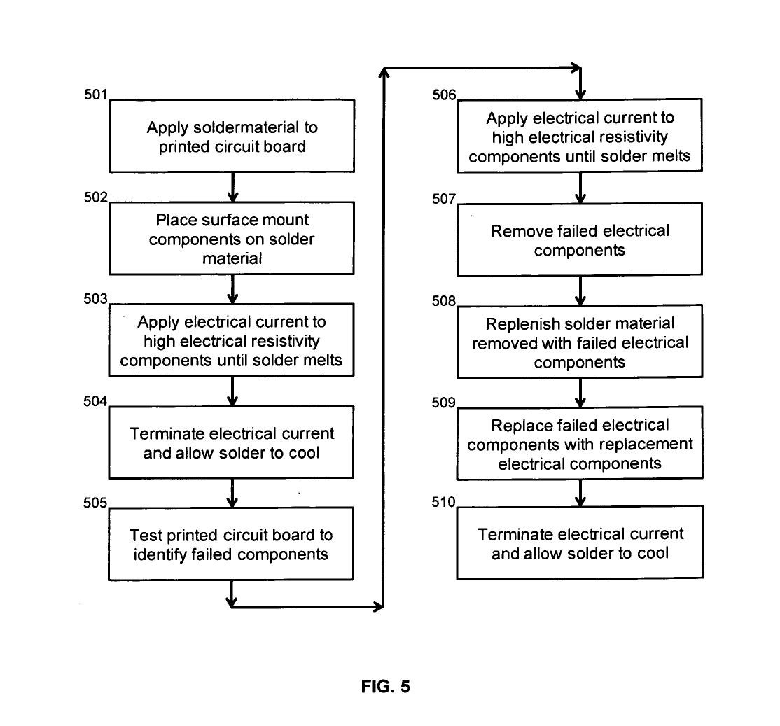

FIG. 5 is a second illustrative process flow diagram of the present invention. This process flow diagram includes an illustrative series of rework steps. The first several steps of the second illustrative process flow mirror those of the first illustrative process flow described by FIG. 4, but are repeated here for clarity. In the first step 501 solder material is applied to solder pads 603 on the printed circuit board. The solder material may take a variety of forms such as electroplated solder, waver solder or solder paste. The solder material may also be deposited by a variety of methods including electroplating, wave solder and screen printing. These materials and methods are intended to be illustrative and not restrictive. The invention can be modified to include a number of different solder materials and deposition methods not described here that are known in the art without deviating from the spirit and scope of the invention.

In the second step 502 of the second illustrative process flow surface mount electrical components 620 are placed on the solder materials. Mechanical pick and place machines are commonly used to places electrical components at this process step.

In the third step 503 of the second illustrative process flow an electrical current is applied to buried high electrical resistivity components 613. This results in localized heating. In this manner only the material in close physical proximity to the high electrical resistivity components 613 are heated including the solder pads 603, applied solder material, and the electrical components 620. This process step is maintained until the applied solder material is heated to above its reflow temperature, melts and wets the solder pads 603 and the electrical contact surfaces of the electrical components 620.

In the fourth step 504 of the second illustrative process flow the electrical current applied to the buried high electrical resistivity components 613 is terminated and the solder is allowed to cool and solidify.

In the fifth step 505 of the second illustrative process flow the printed circuit board is tested to identify electrical component failures.

In the sixth step 506 of the second illustrative process flow an electrical current is applied to the high electrical resistivity components 613 associated with the failed electrical components. This current is maintained until the solder enters a molten state.

In the seventh step 507 of the second illustrative process flow the failed electrical components are removed. During this step some solder material will remain on failed electrical component. This may leave an inadequate amount of solder material to form an effective solder bond.

In the eighth step 508 of the second illustrate process flow sold material is replenished if an inadequate amount of solder material remains. The replenished solder material may take a variety of form including but not limited to: application of solder paste material to the solder pads of the replacement electrical component or addition of solder material to the molten solder on the printed circuit board.

In the ninth step 509 of the second illustrative process flow the failed electrical components are replaced with replacement electrical components. The current applied to the high electrical resistivity components is maintained until all replenished solder material is molten and the molten solder wets the electrical contact features of the replaced electrical component.

In the tenth step 510 of the second illustrative process flow the electrical is terminated and the molten solder material is allowed to cool and solidify.

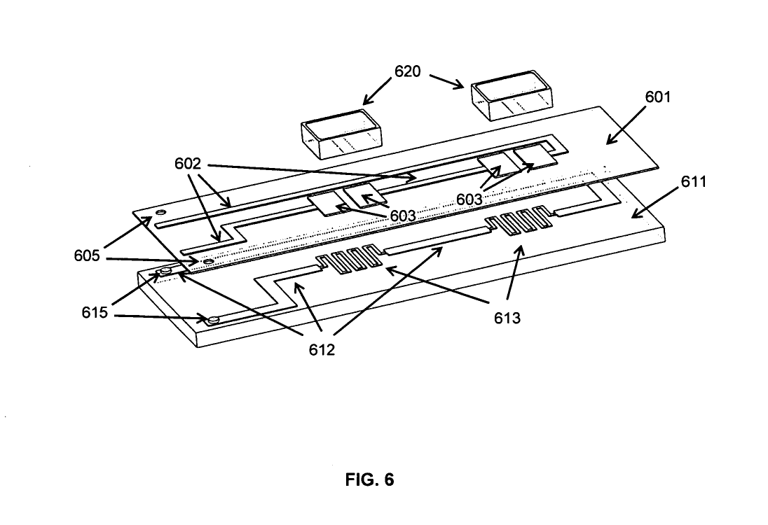

FIG. 6 illustrates one embodiment of the present invention. The printed circuit board of this embodiment comprises a first electrically insulating layer 601 and a second insulating layer 611. At least one set of electrically conductive traces are located on the outer surface of the first electrically insulating layer 601. These electrical traces 602 include solder pads 603 for mounting at least one electrical component 620.

This embodiment further includes at least once set of electrically conductive traces 612 on the second electrically insulating layer 611. These electrical traces 612 on the second electrically insulating layer 611 include at least once high electrically resistive element 613 located proximal to at least one of the solder pads 603 disposed on the first electrically insulating layer 601.

The first electrically insulating layer 601 further includes holes or electrical vias 605 that allow electrical contact to be made to the electrically conductive traces 612 disposed on the second electrically insulating layer 611.

Electrical contact 615 may also be located on the electrically conductive traces 612 disposed on the second electrically insulating layer 611. If present these electrical contacts 615 should be aligned with holes or electrical vias 605 present in the first electrically insulating layer so that electrical contact may be made to the electrical traces 612 disposed on the second electrically insulating layer 611.

When an electrical current is applied to an electrical circuit the net electrical resistivity can be calculated if both the applied voltage and the current are known. The electrical resistance in Ohms is simply the applied electrical voltage in Volts divided by the electric current in Amps. In addition the electrical resistivity of materials changes in a predictable way with respect to temperature. These facts are commonly used to make temperature measurements and these principles may be used in the present invention. Typically the electrical resistivity of metals increases with increasing temperature. This is in contradiction to the electrical resistivity of semiconductor materials which decreases with increasing temperature. The exact nature of the change in electrical resistivity with temperature is not a critical aspect of the present invention, only the fact that electrical resistivity of components changes with temperature is important as long as the nature of this change is understood.

By monitoring both the electrical current applied to the high electrical resistivity components and the applied electrical voltage associated with the electrical current it is possible to determine the resistance of the high electrical resistivity electrical component 613 and hence its temperature. This allows a unique processing step not possible in prior art solder reflow methods. The temperature of the high electrical resistivity components 613 can be controlled over a wide variety of ranges and match any desired temperature profile.

It is also useful to note that as heat is absorbed by a solid material its temperature increases until it begins melting. Once it starts melting both solid and phases of the solder material will be in contact with each other and be in thermal equilibrium. Enough heat must be absorbed by the solid material to overcome the latent heat of melting. Once this occurs the material is completely in a liquid or molten state and continued addition of heat will once again result in increases in the temperature of the material.

In a similar manner as heat is removed from a liquid material its temperature decreases until the material starts to solidify. Once this happens removal additional heat will result in liquid material transforming to a solid at the same temperature. Once again the temperature will remain constant until enough heat has been removed to overcome the latent heat of fusion of the liquid. When all of the material has solidified removal of additional heat will once again result in a decrease in temperature of the material.

Latent heat of melting and latent heat of fusion are equivalent parameters with the only difference being that latent heat of melting applies to a material transitioning from a solid state to a liquid state while latent heat of fusion applies to a material transitioning from a liquid state to a solid state. Both melting and freezing are equilibrium processes and occur at a constant temperature for any given pressure.

Thus when applying an electrical current to the high electrical resistivity components 613 and tracking both the applied electrical voltage and the applied electrical current it is possible to determine the both the applied power and the temperature of the high electrical resistivity components 613.

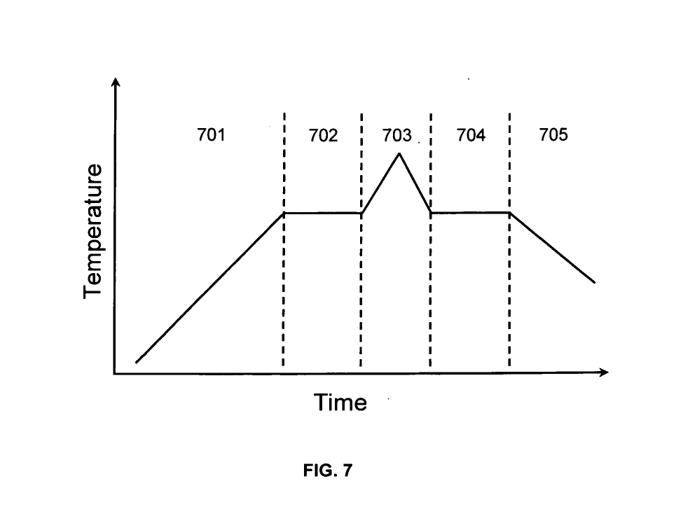

FIG. 7 illustrates process control data that can be derived from this information from a solder reflow process of the present invention. As an electrical current is applied to a high electrical resistivity component 613 the voltage applied is tracked to determine the temperature of the high electrical resistivity component 613 which can be tracked versus time.

Collecting data in this manner will allow identification of a first process step 701 in which the temperature of the high electrical resistivity component 613 increases with temperature. During this process step 701 the solder material is being heated.

In the second process step 702 the temperature of the high electrical resistivity component 613 will constant or nearly constant. In this process step the solder material is melting. At the end of this process step 702 the solder material will be completely melted and the temperature will once again begin rising 703.

In the third process step 703 the temperature is shown as increasing to a maximum and then decreasing. This bridges steps 403 and 404 of the first illustrative process shown in FIG. 4.

Monitoring the temperature of the high electrical resistivity electrical component 613 is not possible if the current is completely terminated. In order to monitor the temperature the applied electrical current can be reduced to a level that allows accurate measurement of the voltage without generating enough heat to maintain the solder material in a molten state.

By this method the temperature will be seen to decrease until the solder material begins to solidify. At this point the process enters a fourth step 704 during which the temperature of the high electrical resistivity component will be constant or nearly constant. This process step will continue until all the solder material is once again in a solid state and the process enters a fifth step 705.

In the fifth process step 705 the temperature will continue to decrease as the solder continues to cool. As all the solder material is now solid the electrical current applied to the high electrical resistivity component may be discontinued as process monitoring is no longer useful.

Access to information on the temperature of solder material during the entire process of heating, melting and cooling of the solder material offers a powerful tool to reduce the utility requirements for a solder reflow process. Thus the present invention allows the ability to apply a minimal amount of thermal energy for the minimal amount of time.

Utilizing this process information it is possible to reduce the utility requirements for a reflow process by two or even three orders of magnitude while simultaneously reducing process time and floor space requirements.

While the invention has been described in detail in connection with only a limited number of embodiments, it should be readily understood that the invention is not limited to such disclosed embodiments. Rather, the invention can be modified to incorporate any number of variation, alterations, substitutions or equivalent arrangements not heretofore described, but which are commensurate with the spirit and scope of the invention. Additionally, while various embodiments of the have been described, it is to be understood that aspects of the invention may include only some of the described embodiments. Accordingly, the invention is not to be seen as limits by the foregoing description, but is only limited by the scope of the appended claims.

The invention claimed is:

1. A multi-layer printed circuit board comprising:
a first insulating layer having a first surface and a second surface
at least one set of electrically conductive traces disposed on the first surface of the first insulating layer wherein said set of electrically conductive traces includes at least one solder pad for at least one electrical component
a second insulating layer having a first surface and a second surface, said second insulating layer disposed such that the first surface of the second insulating layer is adjacent to the second surface of the first insulating layer
at least one set of electrically conductive traces disposed on said first surface of said second insulating layer wherein said set of electrically conductive traces disposed on said first surface of said second insulating layer includes at least one high electrical resistivity element located proximal to at least one solder pad disposed on said first surface of said first insulating layer wherein said set of electrically conductive traces disposed on said first surface of said second insulating layer further includes at least one set of electrically conductive vias that extend from said set of electrically conductive traces disposed on said first surface of said second insulating layer through said first insulating layer to said first surface of said first insulating layer

2. A process for soldering at least one surface mount electrical component to a printed circuit board of claim 1 comprising:
applying solder material to at least one set of solder pads to said printed circuit board
placing a surface mount electrical component on said solder material
applying an electrical current to at least one buried high electrical resistivity component proximal to said solder pads to induce localized heating of said solder material to a temperature above the reflow temperature of said solder material so that said solder material enters a molten state
maintaining said electrical current for a time sufficient for said molten solder material to wet the electrical contact features of said surface mount electrical component thereby establishing electrical contact between said printed circuit board and said surface mount component
discontinuing said applied electrical current and allowing said molten solder material to cool and solidify

3. A process for soldering at least one through hole electrical component to a printed circuit board of claim 1 comprising:
applying solder material to at least one solder pad surrounding a through hole in said printed circuit board
placing a through hole electrical component through said hole with said solder material
applying an electrical current to at least one buried high electrical resistivity component proximal to said solder pad to cause localized heating of said solder material to a temperature above the reflow temperature of said solder material so that said solder material enters a molten state
maintaining said electrical current for a time sufficient for said molten solder material to wet the electrical contact features of said through hole electrical component thereby establishing electrical contact between said printed circuit board and said through hole electrical component
discontinuing said electrical current and allowing said molten solder material to cool and solidify

4. A process for reworking a printed circuit board of claim 1 comprising:
testing one or more electrical components soldered to said printed circuit board of to identify a failed component
applying an electrical current to at least one buried high electrical resistivity component proximal to one or more solder pads of said failed electrical component to cause localized heating of solder material attaching said failed electrical component to said printed circuit board to a temperature above the reflow temperature so that said solder material enters a molten state
removing said failed electrical component
replacing said failed electrical component with a replacement electrical component
maintaining said electrical current until said molten solder material wets the electrical contact features of said replaced electrical component thereby establishing an electrical connection between said printed circuit board and said replaced electrical component
discontinuing said electrical current and allowing said molten solder material to solidify

5. A process for reworking a printed circuit board of claim 1 comprising:
testing one or more electrical components soldered to a said printed circuit board of to identify a failed component
applying an electrical current to at least one buried high electrical resistivity component proximal to one or more solder pads of said failed electrical component to cause localized heating of solder material attaching said failed electrical component to said printed circuit board to a temperature above the reflow temperature of said solder material so that said solder material enters a molten state
removing said failed electrical component
replenishing solder material on said printed circuit board to replace solder material removed with said failed electrical component
replacing said failed electrical component with a replacement electrical component
maintaining said electrical current until said solder material wets one or more electrical contact features of said replaced electrical component thereby establishing an electrical connection between said printed circuit board and said replaced electrical component
discontinuing said electrical current and allowing said molten solder material to solidify

6. A process for reworking a printed circuit board of claim 1 comprising:
testing one or more electrical components soldered to said printed circuit board to identify a failed component
applying an electrical current to at least one buried high electrical resistivity component proximal to one or more solder pads of said failed electrical component to cause localized heating of solder material attaching said failed electrical component to said printed circuit board to a temperature above the reflow temperature of said solder material so that said solder material enters a molten state
removing said failed electrical component
applying solder material to a replacement electrical component sufficient to replenish solder material removed with said failed electrical component
bringing said replacement solder material on said replacement electrical component into physical contact with molten solder material on the solder pads associated with said failed electrical component which was removed
maintaining said physical contact with said replacement solder material and said molten solder material until said replacement solder material is raised to a temperature above its reflow temperature thereby establishing an electrical connection between said printed circuit board and said replacement electrical component
discontinuing said electrical current and allowing said molten solder material to solidify

7. A process for soldering electrical components to a printed circuit board comprising:
applying a solder material to at least one solder pad disposed on said printed circuit board
placing at least one electrical component on said applied solder material
heating said applied solder material with said placed electrical component by applying an electrical current to a high electrical resistivity component proximal to said applying solder material and said placed electrical component to cause localized heating
monitoring the temperature of said high electrical resistivity component by monitoring the electrical current applied to said high electrical resistivity component and the voltage applied to said high electrical resistivity component
maintaining said electrical current applied to said high electrical resistivity component until said solder material is raised to a temperature above its melting point
reducing the electrical current applied to said high electrical resistivity component allowing cooling of the solder material while monitoring said applied electrical current and the voltage applied to said high electrical resistivity component
maintaining said reduced applied electrical current to said high electrical resistivity component until said applied solder material has and fully solidified.

8. A printed circuit board comprising:
a first insulating layer having a first surface and a second surface
at least one set of electrically conductive traces disposed on the first surface of the first insulating layer wherein said set of electrically conductive traces includes at least one solder pad for at least one electrical component
at least one set of electrically conductive traces disposed on said first surface of said first insulating layer wherein said set of electrically conductive traces disposed on said first surface of said first insulating layer includes at least one high electrical resistivity element located proximal to at least one solder pad disposed on said first surface of said first insulating layer

9. A process for soldering at least one surface mount electrical component to a printed circuit board of claim 8 comprising:
applying solder material to at least one set of solder pads to said printed circuit board
placing a surface mount electrical component on said solder material
applying an electrical current to at least one high electrical resistivity component proximal to said solder pads to induce localized heating of said solder material to a temperature above the reflow temperature of said solder material so that said solder material enters a molten state
maintaining said electrical current for a time sufficient for said molten solder material to wet the electrical contact features of said surface mount electrical component thereby establishing electrical contact between said printed circuit board and said surface mount component
discontinuing said applied electrical current and allowing said molten solder material to cool and solidify

10. A process for soldering at least one through hole electrical component to a printed circuit board of claim 8 comprising:
applying solder material to at least one solder pad surrounding a through hole in a said printed circuit board
placing a through hole electrical component through said hole with said solder material
applying an electrical current to at least one high electrical resistivity component proximal to said solder pad to cause localized heating of said solder material to a temperature above the reflow temperature of said solder material so that said solder material enters a molten state
maintaining said electrical current for a time sufficient for said molten solder material to wet the electrical contact features of said through hole electrical component thereby establishing electrical contact between said printed circuit board and said through hole electrical component
discontinuing said electrical current and allowing said molten solder material to cool and solidify

11. A process for reworking a printed circuit board of claim 8 comprising:
testing one or more electrical components soldered to said printed circuit board to identify a failed component
applying an electrical current to at least one high electrical resistivity component proximal to one or more solder pads of said failed electrical component to cause localized heating of solder material attaching said failed electrical component to said printed circuit board to a temperature above the reflow temperature so that said solder material enters a molten state
removing said failed electrical component
replacing said failed electrical component with a replacement electrical component
maintaining said electrical current until said molten solder material wets the electrical contact features of said replaced electrical component thereby establishing an electrical connection between said printed circuit board and said replaced electrical component
discontinuing said electrical current and allowing said molten solder material to solidify

12. A process for reworking a printed circuit board of claim 8 comprising:
testing one or more electrical components soldered to said printed circuit board to identify a failed component
applying an electrical current to at least one high electrical resistivity component proximal to one or more solder pads of said failed electrical component to cause localized heating of solder material attaching said failed electrical component to said printed circuit board to a temperature above the reflow temperature of said solder material so that said solder material enters a molten state
removing said failed electrical component
replenishing solder material on said printed circuit board to replace solder material removed with said failed electrical component
replacing said failed electrical component with a replacement electrical component
maintaining said electrical current until said solder material wets one or more electrical contact features of said replaced electrical component thereby establishing an electrical connection between said printed circuit board and said replaced electrical component
discontinuing said electrical current and allowing said molten solder material to solidify

13. A process for reworking a printed circuit board of claim 8 comprising:
testing one or more electrical components soldered to said printed circuit board to identify a failed component
applying an electrical current to at least one high electrical resistivity component proximal to one or more solder pads of said failed electrical component to cause localized heating of solder material attaching said failed electrical component to said printed circuit board to a temperature above the reflow temperature of said solder material so that said solder material enters a molten state
removing said failed electrical component
applying solder material to a replacement electrical component sufficient to replenish solder material removed with said failed electrical component
bringing said replacement solder material on said replacement electrical component into physical contact with molten solder material on the solder pads associated with said failed electrical component which was removed
maintaining said physical contact with said replacement solder material and said molten solder material until said replacement solder material is raised to a temperature above its reflow temperature thereby establishing an electrical connection between said printed circuit board and said replacement electrical component
discontinuing said electrical current and allowing said molten solder material to solidify
